(19) United States
(12) Patent Application Publication
(10) Pub. No.: US 2024/0417594 A1
(43) Pub. Date: Dec. 19, 2024

(54) Chemical Mechanical Planarization Polishing Composition For Silicon Oxide And Silicon Nitride

(71) Applicant: Versum Materials US, LLC, Tempe, AZ (US)

(72) Inventors: Maitland Graham, Chandler, AZ (US); HONGJUN ZHOU, Chandler, AZ (US)

(21) Appl. No.: 18/712,750

(22) PCT Filed: Nov. 29, 2022
(86) PCT No.: PCT/US2022/080590

§ 371 Date: May 23, 2024

Related U.S. Application Data
(60) Provisional application No. 63/264,800, filed on Dec. 2, 2021.

(51) Int. Cl. C09G 1/02; B24B 7/22; H01L 21/3105

(52) U.S. Cl. CPC C09G 1/02; B24B 7/228; H01L 21/31053

(57) ABSTRACT

The present invention discloses Chemical Mechanical Planarization (CMP) polishing compositions, methods and systems that offer high and near equal removal rates of silicon dioxide and silicon nitride for achieving a topographically corrected wafer surface with low defects. The CMP polishing compositions use a unique combination of non-spherical, non-surface modified silica particles having low specific surface area (<300 or <150 m²/gm) due to low surface silanol density (<4 SiOH/nm²); and a chemical additive contains diphosphonic acid.

### CROSS REFERENCE TO RELATED PATENT APPLICATIONS

The present patent application claims the benefit of U.S. Provisional Patent Application Ser. No. 63/264,800 filed on Dec. 2, 2021, which is entirely incorporated herein by reference.

### BACKGROUND OF THE INVENTION

The present disclosure relates to chemical mechanical planarization or polishing (“CMP”) slurries (or compositions, or formulations), polishing methods and polishing systems for carrying out chemical mechanical planarization in the production of a semiconductor device.

Chemical Mechanical Planarization (CMP) polishing is a key process step in the fabrication of integrated circuits, especially polishing surfaces for the purpose of recovering a selected material and planarizing the structure. As the technology for integrated circuit devices advances, CMP polishing is used in new and different ways to meet the new performance needed for advanced integrated circuits.

Silicon oxide and silicon nitride are important materials used in the fabrication of microelectronics devices. They are used in various combinations to achieve new and more complex device configurations. In general, the structural complexity and performance characteristics vary across different applications. Thus, CMP polishing process has to be adjusted to meet the polishing requirements for particular devices.

For example, in a typical shallow trench isolation (STI) process, CMP polishing compositions have been developed having selectivity for either removal of silicon dioxide or silicon nitride.

Polishing compositions having selectivity for silicon dioxide remove silicon dioxide at a greater rate than silicon nitride, and when overlying silicon dioxide is substantially removed to expose underlying silicon nitride to the polishing composition, the overall material removal rate drops, thereby allowing silicon nitride to act as a stopping layer. Typically, once the overlying silicon dioxide has been removed, a second polishing step using a polishing composition having selectivity for silicon nitride over silicon dioxide is employed to remove the silicon nitride layer, whereby the low polishing rate for silicon dioxide exhibited by such polishing composition minimizes the undesirable removal of silicon dioxide remaining in the trenches.

Prior works to provide the composition for selective removal include, for example, U.S. Pat. No. 6,491,943; US2,013,248,756; U.S. Pat. No. 6,616,514; US20200354610; and US20,160,160,083.

In the specific area of non-selective oxide buff, such a CMP composition is engineered to remove silicon dioxide and silicon nitride at near equal removal rates to achieve a topographically corrected wafer surface with low defects to prepare the wafer ready for the next downstream process step of microchip fabrication.

Prior works to provide the composition for non-selective oxide buff include, for example, U.S. Pat. No. 9,190,286; US20090090696; US20200354609; U.S. Pat. No. 9,617,450; US20200354610; and U.S. Pat. No. 9,617,450.

It should be readily apparent from the foregoing that there remains a need within the art for compositions, methods and systems of CMP polishing that that allow for the removal rates of various layers, specifically, silicon oxide and silicon nitride to be adjusted or tuned during CMP process to meet the polishing requirements for particular devices.

### BRIEF SUMMARY OF THE INVENTION

The present invention satisfies the need by providing Chemical mechanical Planarization (CMP) polishing compositions, methods, and systems for non-selective oxide buff applications.

The disclosed CMP polishing composition has a unique combination of using silica particles with low specific surface area (SSA) due to low surface silanol density, and a chemical additives contains diphosphonic acid. for example, etidronic acid, to provide high and near equal removal rates of silicon dioxide (such as TEOS) and silicon nitride (SiN) for achieving a topographically corrected wafer surface with low defects.

More specifically, the disclosed CMP polishing compositions use non-surface modified silica particles having low specific surface area (SSA) due to low silanol density The silica particles have a low silanol density <4, <3, <2, <1, <0.5, <0.1, <0.05, or <0.01 SiOH/nm², or specific surface area (SSA) of <300, <250, <200, <150, or <120 m²/gm.

In one aspect, there is provided a CMP polishing composition comprises:
silica particles having low SSA;
a chemical additives contains phosphonic acid.
a solvent; and
optionally
biocide; and
pH adjustor;
wherein
the composition has a pH of 1 to 6, 1.5 to 5, or 2 to 4.

The silica particles include, but are not limited to colloidal silica, high purity colloidal silica, and fumed silica. The particles can have any suitable shapes: spherical, non-spherical such as cocoon shaped, branched, or aggregated silica particles.

The silica particles have a low silanol density <4, <3, <2, <1, <0.5, <0.1, <0.05, or <0.01 SiOH/nm², or specific surface area (SSA) of <300, <250, <200, <150, or <120 m²/gm.

The silica particles are not surface treated or modified by any chemical species, such as nitrogen-containing species for example aminosilane. Thus, the surface of the particles is not covalently bonded with either a negatively or a positively charged species.

The Mean Particle Size (MPS) of silica particles is ranged from 10 nm to 500 nm, the preferred particle size is ranged from 20 nm to 300 nm, the more preferred particle size is ranged from 50 nm to 250 nm. The MPS is measured by dynamic light scattering (DLS).

The preferred silica particles are cocoon shaped, non-surface modified, and having silanol density of <0.5, <0.1, <0.05, or <0.01 SiOH/nm², or having specific surface area (SSA) of <150, or <120 m²/gm.

The solvent includes but is not limited to deionized (DI) water, distilled water, and alcoholic organic solvents.

The pH adjustor that can adjust the pH of the formulation without inhibiting the non-selectivity attributes of the chemical additive.

The pH adjustor include but are not limited to inorganic acids, inorganic bases, or amino acids.

The pH adjustor include but are not limited to amino acid selected from the group consisting of L-glutamic acid, L-histidine, alanine, glycine, cysteine, cystine, aspartic acid, valine, and serine; inorganic acid selected from the group consisting of nitric acid, sulfuric acid, hydrochloric acid and phosphoric acid; inorganic bases selected from the group consisting of ammonium hydroxide, sodium hydroxide, potassium hydroxide, and cesium hydroxide; and tetramethylammonium hydroxide, tetraethylammonium hydroxide, tetrabutylammonium hydroxide, tetrabutylphosphonium hydroxide, piperazine, and ethylenediamine.

The preferred pH adjustor include but are not limited to L-glutamic acid, L-histidine, alanine, serine, sulfuric acid, nitric acid, ammonium hydroxide.

The chemical additives include but are not limited to any organic acid containing a phosphorus atom, preferably an organic acid containing a phosphonic acid, or more preferably an organic acid containing two or more phosphonic acids.

The chemical additives include but are not limited to: etidronic acid (or 1-hydroxyethane-1 1-diphosphonic acid), methylenediphosphonic acid, nitrilotris(methylene triphosphonic acid), phenylphosphonic acid, octylphosphonic acid, butylphosphonic acid, (aminomethyl)phosphonic acid, diisooctylphosphinic acid, iminodi(methylphosphonic acid), and 3-phosphonopropionic acid.

The biocide includes, but is not limited to, Kathon™, Kathon™ CG/ICP II, from Dupont/Dow Chemical Co. Bioban or Neolone M10 from Dupont/Dow Chemical Co. They have active ingredients of 5-chloro-2-methyl-4-isothiazolin-3-one and/or 2-methyl-4-isothiazolin-3-one.

In another aspect, there is provided a method of CMP polishing a substrate having at least one surface comprising silicon dioxide using the CMP polishing composition described above.

In yet another aspect, there is provided a system of CMP polishing a substrate having at least one surface comprising silicon dioxide using the CMP polishing composition described above.

The polished oxide films can be Chemical vapor deposition (CVD), Plasma Enhance CVD (PECVD), High Density Deposition CVD (HDP), or spin on oxide films.

The substrate disclosed above can further comprises at least a surface containing Poly-Si, silicon nitride, or both Poly-Si and silicon nitride. The removal selectivity of SiO₂: SiN is from 0.5 to 2, 0.8 to 1.5, 0.9 to 1.1, or 0.95 to 1.05.

### DETAILED DESCRIPTION OF THE INVENTION

The present invention provides Chemical mechanical Planarization (CMP) polishing compositions, methods, and systems for non-selective oxide buff applications.

The CMP polishing composition has a unique combination of using silica particles with low silanol density, and suitable chemical additives such as etidronic acid to provide high and near equal removal rates of silicon dioxide (such as TEOS) and silicon nitride (SiN) for achieving a topographically corrected wafer surface with low defects.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of all examples, or exemplary language (e.g., “such as”) provided herein, is intended merely to better illuminate the invention, and does not pose a limitation on the scope of the invention unless otherwise claimed. No language in the specification should be construed as indicating any non-claimed element as essential to the practice of the invention. The use of the term “comprising” in the specification and the claims includes the narrower language of “consisting essentially of” and “consisting of.”

Embodiments are described herein, including the best mode known to the inventors for carrying out the invention. Variations of those embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law.

Moreover, any combination of the above-described elements in all possible variations thereof is encompassed by the invention unless otherwise indicated herein or otherwise clearly contradicted by context.

For ease of reference, “microelectronic device” corresponds to semiconductor substrates, flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” is not meant to be limiting in any way and includes any substrate that will eventually become a microelectronic device or microelectronic assembly.

“Substantially free” is defined herein as less than 0.001 wt. %. “Substantially free” also includes 0.000 wt. %. The term “free of” means 0.000 wt. %.

As used herein, “about” is intended to correspond to ±5%, preferably ±2% of the stated value.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.00001 weight percent, based on the total weight of the composition in which such components are employed.

The specific surface area used here is defined as the surface area of the solid particle divided by the mass of the solid particle as per unit area of mass or m²/gram (gm). The specific surface area for the abrasive particles such as silica particles has been measured by Sears titration method. The specific surface area of silica particles is inter-related to the surface silanol density of the particles, as described in equation 1 of “Size-dependent physiochemical and optical properties of silica nanoparticles,” (Materials Chemistry and Physics, 114 (2009) 328-332 I. A. Rahmana, P. Vejayakumarana, C. S. Sipaut a, J. Ismail a, C. K. Chee b).

Abrasive particles having standard surface silanol density are described as having ≥5 SiOH/nm² silanol density or having >350 m²/gm or >300 m²/gm specific surface area (SSA); and abrasive particles having low surface silanol density are described as having <4, <3, <2, <1, <0.5, <0.1, <0.05, or even <0.01 SiOH/nm² silanol density, or having <300, <250, <200, <150, or <120 m²/gm specific surface area (SSA).

There are several specific aspects of the present invention.

In one aspect, there is provided a CMP polishing composition comprises:
silica particles having low specific surface area (SSA) due to low surface silanol density;
at least one chemical additive; a rate boosting additive
a solvent; and
optionally
biocide; and
pH adjustor;
wherein
the composition has a pH of 1 to 6, 1.5 to 5, or 2 to 4.

The silica particles include, but are not limited to colloidal silica, high purity colloidal silica, and fumed silica. The particles can have any suitable shapes: spherical, non-spherical such as cocoon shaped, branched, or aggregated silica particles.

The silica particles have a low silanol density of <4, <3, <2, <1, <0.5, <0.1, <0.05, or <0.01 SiOH/nm², or specific surface area (SSA) of <300, <250, <200, <150, or <120 m²/gm.

The silica particles are not surface treated or modified by any chemical species, such as a nitrogen-containing species for example aminosilane. Thus, the surface of the particles is not covalent bonded with either a negatively or a positively charged species.

The Mean Particle Size (MPS) of silica particles is ranged from 30 nm to 500 nm, the preferred particle size is ranged from 40 nm to 300 nm, the more preferred particle size is ranged from 50 nm to 250 nm. The MPS is measured by dynamic light scattering (DLS).

The preferred silica particles are cocoon shaped, non-surface modified, and having SiOH/nm² level of <4, <3, <2, <1, <0.5, <0.1, <0.05, or <0.01, or having specific surface area (SSA) of <300, <250, <200, <150, or <120 m²/gm.

The concentrations of silica particles range from 0.01 wt. % to 20 wt. %, the preferred concentrations range from 0.05 wt. % to 10 wt. %, the more preferred concentrations range from 0.1 wt. % to 5 wt. %.

The solvent includes but is not limited to deionized (DI) water, distilled water, and alcoholic organic solvents.

The preferred solvent is DI water.

The pH adjustor that can adjust the pH of the formulation without inhibiting the non-selectivity attributes of the chemical additive.

The pH adjusters include inorganic acids, inorganic bases or amino acids.

The pH adjusters include but are not limited to: L-glutamic acid, alanine, glycine, cysteine, cystine, aspartic acid, valine, and serine. Inorganic acids such as nitric acid, sulfuric acid, hydrochloric acid and phosphoric acid. Inorganic bases such as ammonium hydroxide, sodium hydroxide, potassium hydroxide, and cesium hydroxide and organic bases such as tetramethylammonium hydroxide, tetraethylammonium hydroxide, tetrabutylammonium hydroxide, tetrabutylphosphonium hydroxide, piperazine, and ethylenediamine.

The preferred pH adjustor include but are not limited to L-glutamic acid, L-histidine, alanine, serine, sulfuric acid, nitric acid, ammonium hydroxide.

The CMP slurry contains 0.01 wt. % to 2.0% wt. %, 0.03 wt. % to 0.75 wt. %, or 0.03 wt. % to 0.5 wt. % of pH adjuster.

The CMP slurry has a pH ranged from 1 to 6, 1.5 to 5, or 2 to 4.

The chemical additives include but are not limited to any organic acid containing a phosphorus atom, preferably an organic acid containing a phosphonic acid, or more preferably an organic acid containing two or more phosphonic acids.

The chemical additives include but are not limited to: etidronic acid (or 1-hydroxyethane-1 1-diphosphonic acid), and methylenediphosphonic acid, nitrilotris(methylene triphosphonic acid), phenylphosphonic acid, octylphosphonic acid, butylphosphonic acid, (aminomethyl)phosphonic acid, diisooctylphosphinic acid, iminodi(methylphosphonic acid) and 3-phosphonopropionic acid.

The CMP slurry contains 0.01 wt. % to 2.0% wt. %, 0.03 wt. % to 0.75 wt. %, or 0.03 wt. % to 0.5 wt. % of the chemical additive.

The biocide includes, but is not limited to, Kathon™, Kathon™ CG/ICP II, from Dupont/Dow Chemical Co. Bioban or Neolone M10 from Dupont/Dow Chemical Co.

They have active ingredients of 5-chloro-2-methyl-4-isothiazolin-3-one and/or 2-methyl-4-isothiazolin-3-one.

The CMP slurry may contain biocide from 0.0001 wt. % to 0.05 wt. %; preferably from 0.0005 wt. % to 0.025 wt. %, and more preferably from 0.001 wt. % to 0.01 wt. %.

The CMP slurries may further comprise surfactant; dispersion agent; chelating agent; and film-foaming anticorrosion agent, corrosion inhibitor.

In another aspect, there is provided a method of CMP polishing a substrate having at least one surface comprising silicon dioxide using the CMP polishing composition described above.

In yet another aspect, there is provided a system of CMP polishing a substrate having at least one surface comprising silicon dioxide using the CMP polishing composition described above.

The polished oxide films can be Chemical vapor deposition (CVD), Plasma Enhance CVD (PECVD), High Density Deposition CVD (HDP), or spin on oxide films.

The substrate disclosed above can further comprises at least a surface containing Poly-Si, silicon nitride, or both Poly-Si and silicon nitride. The removal selectivity of SiO₂: SiN is from 0.5 to 2, 0.8 to 1.5, 0.9 to 1.1, or 0.95 to 1.05.

Other aspects, features and embodiments of the invention will be more fully apparent from the ensuing disclosure and appended claims.

The embodiments of the invention can be used alone or in combinations with each other.

The following non-limiting examples are presented to further illustrate the present invention.

### CMP Methodology

In the examples presented below, CMP experiments were run using the procedures and experimental conditions given below.

### Glossary

### Components

Silica particles: used as abrasive having a primary particle size of approximately 30 nm; and the secondary particles size ranged from 50 to 150 nm.

The particles PL-3, BS-3, PL-3H, BS-3H, PL-3L and PL-5 (with varied sizes) were supplied by Fuso Inc. in Japan.

Chemicals, such as etidronic acid, L-glutamic acid and other chemical raw materials were purchased from Sigma-Aldrich (Merck KGaA) of highest commercial grade and used as received unless otherwise specified.

Polishing Pad: Fujibo H800, was used during CMP, supplied by Fujibo Ehime Co., Ltd. 272 Oshinden, Saijo-shi, Ehime 799-1342, Japan.

### Parameters

### General

Å or A: angstrom(s)—a unit of length
BP: back pressure, in psi units
CMP: chemical mechanical planarization=chemical mechanical polishing
CS: carrier speed
DF: Down force: pressure applied during CMP, unit's psi
min: minute(s)
ml: milliliter(s)
mV: millivolt(s)
psi: pounds per square inch
PS: platen rotational speed of polishing tool, in rpm (revolution(s) per minute)
SF: slurry flow, ml/min
SSA: specific surface area (m²/gm)
Wt. %: weight percentage (of a listed component)
TEOS: tetraethyl orthosilicate
TEOS: SiN Selectivity: (removal rate of TEOS)/(removal rate of SiN)
HDP: high density plasma deposited TEOS
TEOS or HDP Removal Rates: Measured TEOS or HDP removal rate at a given down pressure. The down pressure of the CMP tool was 2.0 psi in the examples listed below.
SiN Removal Rates: Measured SiN removal rate at a given down pressure. The down pressure of the CMP tool was 2.0 psi in the examples listed.

### Metrology

Films were measured with a an Optiprobe 5000, manufactured by Therma-Wave, Inc., 1250 Reliance Way, Fremont, CA, 94539. The Optiprobe 5000 measure film thickness of dielectric materials via ellipsometry

### CMP Tool

The CMP tool that was used is a 200 mm Mirra, or 300 mm Reflexion manufactured by Applied Materials, 3050 Boweres Avenue, Santa Clara, California, 95054.

Polishing condition:
Downforce—2.0 psi
Slurry flow rate—200 mL/min
Platen speed—90 RPM
Head speed—84 RPM

### Wafers

Polishing experiments were conducted using PECVD or LECVD or HD TEOS wafers. These blanket wafers were purchased from Silicon Valley Microelectronics, 2985 Kifer Rd., Santa Clara, CA 95051.

### Polishing Experiments

In blanket wafer studies, oxide blanket wafers, and SiN blanket wafers were polished at baseline conditions.

All other reagents and solvents were purchased from Sigma-Aldrich (Merck KGaA) of highest commercial grade and used as received unless otherwise specified.

### Working Example 1

In the working example, 1.5 wt. % of different silica particles were used in Slurry 1A to Slurry 1D as shown in Table 1.

The CMP compositions had a pH around 2.48 to 2.49 at point of use (POU).

All samples in Table 1 had used etidronic acid at 0.097%, L-glutamic acid at 0.061%, and the biocide Neolone M-10 at 0.0025%.

Results of TEOS and SiN removal rates, and the removal selectivity of TOES: SiN Results are Summarized.

TABLE 1
Abrasive

| | | Abrasive | | | Sec- | |
|---|---|---|---|---|---|---|
| | | Con- | | Primary | ondary | Specific |
| | Abra- | cen- | | Particle | Particle | Surface |
| | sive | tration | Mor- | size | size | Area |
| | Name | (%) | phology | (nm) | (nm) | (m²/gm) |
| Slurry 1A | PL-2L | 1.5 | Spherical | 20 | 20 | ≥350 |
| Slurry 1B | PL-2 | 1.5 | Cocoon | 20 | 50 | 328 |
| Slurry 1C | BS-2 | 1.5 | Cocoon | 20 | 50 | 146 |
| Slurry 1D | BS-2H | 1.5 | Aggregate | 20 | 60 | <150 |

Result

| | | POU | TEOS | SiN | |
|---|---|---|---|---|---|
| | | Con- | Re- | Re- | |
| | | duc- | moval | moval | |
| | POU | tivity | Rate | Rate | TEOS:SiN |
| | pH | (mS/cm) | (Å/min) | (Å/min) | Selectivity |
| Slurry 1A | 2.49 | 1.43 | 409 | 238 | 1.72 |
| Slurry 1B | 2.49 | 1.43 | 485 | 617 | 0.79 |
| Slurry 1C | 2.48 | 1.43 | 893 | 671 | 1.33 |
| Slurry 1D | 2.48 | 1.49 | 685 | 864 | 0.79 |

As shown in Table 1, two examples of CMP compositions using low SSA due to low particles surface silanol density particles (BS-2 and BS-2H) provided the highest removal rates for both TEOS and SiN comparing with particles having standard silanol density (PL-2L and PL-2). The removal selectivity of TEOS: SiN was around 0.79 to 1.33.

BS-2 is the low silanol density or low SSA version of PL-2 where morphology, primary and secondary particle sizes are all the same. However, the CMP composition using BS-2 provided 46% higher TEOS rate and around 9% higher SiN rate.

### Working Example 2

In the working example, 1.5 wt. % of different silica particles were used in Slurry 2A to Slurry 2F as shown in Table 2. All samples used etidronic acid at 0.097 wt. %, L-Glutamic acid at 0.061 wt. % and the biocide Neolone M-10 at 0.0025 wt. %.

The CMP compositions had a pH around 2.43 to 2.49 at point of use (POU).

TABLE 2
Abrasive

| | | Abrasive | | | Sec- | |
|---|---|---|---|---|---|---|
| | | Con- | | Primary | ondary | Specific |
| | Abra- | cen- | | Particle | Particle | Surface |
| | sive | tration | Mor- | size | size | Area |
| | Name | (wt. %) | phology | (nm) | (nm) | (m²/gm) |
| Slurry 2A | PL-3 | 1.5 | Cocoon | 30 | 70 | 319 |
| Slurry 2B | BS-3 | 1.5 | Cocoon | 30 | 70 | 117 |
| Slurry 2C | PL-3H | 1.5 | Aggregate | 30 | 90 | >300 |
| Slurry 2D | BS-3H | 1.5 | Aggregate | 30 | 80 | <150 |
| Slurry 2E | PL-3L | 1.5 | Spherical | 30 | 30 | >300 |
| Slurry 2F | PL-5 | 1.5 | Cocoon | 50 | 110 | >300 |

Results

| | | POU | TEOS | SiN | |
|---|---|---|---|---|---|
| | | Con- | Re- | Re- | |
| | | duc- | moval | moval | |
| | POU | tivity | Rate | Rate | TEOS:SiN |
| | pH | (mS/cm) | (Å/min) | (Å/min) | Selectivity |
| Slurry 2A | 2.46 | 1.49 | 501 | 448 | 1.12 |
| Slurry 2B | 2.43 | 1.48 | 867 | 892 | 0.97 |
| Slurry 2C | 2.45 | 1.48 | 416 | 937 | 0.44 |
| Slurry 2D | 2.46 | 1.48 | 655 | 980 | 0.67 |
| Slurry 2E | 2.46 | 1.47 | 492 | 173 | 2.85 |
| Slurry 2F | 2.49 | 1.43 | 511 | 366 | 1.39 |

As shown in Table 2, again, two examples of CMP compositions using low SSA due to low surface silanol density abrasives (BS-3 and BS-3H) provided significantly higher removal rates for both TEOS and SiN, than the standard silanol density or SSA analogs.

The CMP composition using BS-3 provided 73% and 100% higher TEOS and SiN rates while the composition using BS-3H provided 57% and around 5% higher TEOS and SiN rates.

In addition, CMP composition using BS-3 gave an 0.97 TEOS to SiN removal selectivity showing that a cocoon morphology at around a 70 nm secondary particle size and low silanol density or low SSA is optimal for both high rates and non-selective polish performance.

### Working Example 3

In the working example, 1.5 wt. % of BS-3 silica particles were used in Slurry 3A to Slurry 3H.

In addition to the BS-3 abrasive, different chemical additives were tested in comparison to 1-Hydroxyethane-1,1,-diphosphonic acid (etidronic acid) with BS-3 as shown in Table 3. All additives were added at the same molarity to etidronic acid to control for the additive concentration effect.

The compositions had a pH around 2.28 to 2.6 at point of use (POU).

TABLE 3

| | | | | | TEOS | SiN | |
|---|---|---|---|---|---|---|---|
| | | Additive | | POU | Removal | Removal | |
| | | concen. | POU | conduct. | Rate (Å/ | Rate (Å/ | TEOS:SiN |
| | Additive | (mol/L) | pH | (mS/cm) | min) | min) | Selectivity |
| Slurry 3A | 1- | 0.005 | 2.52 | 2.39 | 869 | 870 | 1.00 |
| | Hydroxyethane-1,1,- | | | | | | |
| | diphosphonic | | | | | | |
| | acid | | | | | | |
| Slurry 3B | Bezenesulfonic | 0.005 | 2.3 | 2.45 | 839 | 176 | 4.77 |
| | acid | | | | | | |
| Slurry 3C | Nitric Acid | 0.005 | 2.6 | 2.41 | 887 | 197 | 4.50 |
| Slurry 3D | Maleic acid | 0.005 | 2.29 | 2.52 | 931 | 187 | 4.98 |
| Slurry 3E | Phosphoric | 0.005 | 2.26 | 2.57 | 974 | 598 | 1.63 |
| | acid | | | | | | |
| Slurry 3F | Nitrilotris(methylene) | 0.005 | 2.39 | 2.25 | 675 | 862 | 0.78 |
| | triphosphonic | | | | | | |
| | acid | | | | | | |
| Slurry 3G | Phenylphosphonic | 0.005 | 2.28 | 2.52 | 882 | 563 | 1.57 |
| | acid | | | | | | |
| Slurry 3H | 3-Phosphonopropionic | 0.005 | 2.28 | 2.52 | 950 | 613 | 1.55 |
| | acid | | | | | | |

The performance of the compositions within the pH range in the table were expected having no difference.

As shown in Table 3, when the chemical additive containing two phosphonic acid (3A) groups was used in combination with the silica particle BS-3, the CMP composition provided high removal rates for TEOS to SiN; and the best TEOS to SiN removal selectivity of 1.00. This is in comparison to several non-phosphonic acid additives (3B-3D) and other single and tri phosphonic acid containing additives (3E to 3H).

Compositions using the chemical additives do not contain phosphonic acid, such as benzenesulfonic acid, maleic acid, and nitric acid (3B-3D) had significantly lower SiN removal rates, and the removal selectivity of TEOS to SiN is >2, or even >3 which provided selective polishing of TEOS.

Furthermore, when the additives containing at least two phosphonic acids (etidronic acid or 1-Hydroxyethane-1,1,-diphosphonic acid) were used in combination with the silica particle BS-3, the CMP composition (3A) provided the best overall polish performance with the best possible removal rates for TEOS to SiN; and TEOS to SiN removal selectivity of 1.00. This is in comparison to several other compositions with phosphonic acid containing additives (3E-3H).

### Working Example 4

In the working example there is a comparison of BS-3C to BS-3 where both BS-3C and BS-3 are 70 nm, cocoon shaped colloidal silicas with SSA <150 m²/gm. BS-3C has a cationic charge in the acidic pH regime. In the example all samples contain 1.5 wt. % of either BS-3 or BS-3C silica particles and have 1-Hydroxyethane-1,1,-diphosphonic acid.

TABLE 4

| | | Abrasive | | | | |
|---|---|---|---|---|---|---|
| | Abras. | concen. | | Additive concen. | | pH adjuster |
| | Type | (wt. %) | Additive | (wt. %) | pH adjuster | (%) |
| Slurry 4A | BS-3 | 1.5 | 1-Hydroxyethane- | 0.097 | L-Glutamic | 0.061 |
| | | | 1,1,-diphosphonic | | Acid | |
| | | | acid | | | |
| Slurry 4B | BS-3C | 1.5 | 1-Hydroxyethane- | 0.097 | L-Glutamic | 0.061 |
| | | | 1,1,-diphosphonic | | Acid | |
| | | | acid | | | |
| Slurry 4C | BS-3 | 1.5 | 1-Hydroxyethane- | 0.097 | — | — |
| | | | 1,1,-diphosphonic | | | |
| | | | acid | | | |
| Slurry 4D | BS-3C | 1.5 | 1-Hydroxyethane- | 0.097 | — | — |
| | | | 1,1,-diphosphonic | | | |
| | | | acid | | | |
| Slurry 4E | BS-3 | 1.5 | 1-Hydroxyethane- | 0.164 | — | — |
| | | | 1,1,-diphosphonic | | | |
| | | | acid | | | |
| Slurry 4F | BS-3C | 1.5 | 1-Hydroxyethane- | 0.164 | — | — |
| | | | 1,1,-diphosphonic | | | |
| | | | acid | | | |
| Slurry 4G | BS-3 | 1.5 | 1-Hydroxyethane- | 0.029 | — | — |
| | | | 1,1,-diphosphonic | | | |
| | | | acid | | | |
| Slurry 4H | BS-3C | 1.5 | 1-Hydroxyethane- | 0.029 | — | — |
| | | | 1,1,-diphosphonic | | | |
| | | | acid | | | |

Results

| | | POU | | | |
|---|---|---|---|---|---|
| | POU | Conductivity | TEOS R. R. | SiN R. R | TEOS:SiN |
| | pH | (mS/cm) | (Å/min) | (Å/min) | Selectivity |
| Slurry 4A | 2.54 | 1.48 | 811 | 836 | 0.97 |
| Slurry 4B | 2.63 | 1.34 | 1046 | 805 | 1.30 |
| Slurry 4C | 2.44 | 1.80 | 844 | 851 | 0.99 |
| Slurry 4D | 2.5 | 1.57 | 1012 | 849 | 1.19 |
| Slurry 4E | 2.24 | 2.81 | 753 | 887 | 0.85 |
| Slurry 4F | 2.28 | 2.59 | 974 | 803 | 1.21 |
| Slurry 4G | 2.87 | 0.65 | 1103 | 662 | 1.67 |
| Slurry 4H | 3.08 | 0.44 | 1014 | 532 | 1.91 |

The compositions had a pH around 2.44 to 3.08 at point of use (POU).

As shown in Table 4, all samples with BS-3 have TEOS: SiN selectivity closer to 1 than the identical sample containing BS-3C. In the case of all samples with BS-3 the lowest selectivity is 0.85 and the highest selectivity is 1.67 whereas the BS-3C has that lowest selectivity of 1.19 and the highest selectivity of 1.91.

For samples 4G and 4H with the lowest concentration of 1-hydroxyethane-1,1,-diphosphonic acid, and thus the highest pH, the TEOS: SiN selectivity diverge the furthest from 1.00 but sample 4G with BS-3 is still significantly better at 1.67.

For sample 4A and 4C, with and without the pH adjustor L-glutamic acid, the respective TEOS to SiN selectivity are nearly identical at 0.97 and 0.99, whereas the respective selectivity for the BS-3C analogs for samples 4B and 4D are 1.3 and 1.19 and have a difference of 0.11. This indicates that the presence of a pH adjustor has more impact on the performance of samples with BS-3C with etidronic acid than with sample with BS-3 and etidronic acid

Generally, the BS-3 (non-surface modified abrasive) samples 4A, 4C, 4D and 4F, when paired with a given concentration of etidronic acid between 0.029 wt. % and 0.164 wt. % are capable of maintaining a TEOS: SiN selectivity closer to 1.00 than the BS-3C (surface modified abrasive).

The working examples have shown that the unique combination of etidronic acid and a low SSA due to low surface silanol density, cocoon or aggregate shaped, non-surface modified, silica particles provides CMP compositions that enables high removal rate polishing of both TEOS and SiN; and achieves non-selective polish performance.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A CMP polishing composition comprising:
silica particles;
a chemical additive containing phosphonic acid;
solvent;
optionally
biocide; and
pH adjuster;
wherein
the composition has a pH of 1 to 6, or 1.5 to 5;
the silica particles having silanol density <4 SiOH/nm²; or specific surface area (SSA) of <300 m²/gm or <150 m²/gm; and
the solvent is selected from the group consisting of deionized (DI) water, distilled water, and alcoholic organic solvents.

2. The CMP polishing composition of claim 1, wherein the silica particles are non-spherical, or non-surface modified.

3. (canceled)

4. (canceled)

5. The CMP polishing composition of claim 1, wherein the pH adjuster is selected from the group consisting of amino acid selected from the group consisting of L-glutamic acid, L-histidine, alanine, glycine, cysteine, cystine, aspartic acid, valine, and serine; inorganic acid selected from the group consisting of nitric acid, sulfuric acid, hydrochloric acid and phosphoric acid; inorganic bases selected from the group consisting of ammonium hydroxide, sodium hydroxide, potassium hydroxide, cesium hydroxide, and tetramethylammonium hydroxide; tetrabutylammonium hydroxide, tetrabutylphosphonium hydroxide, piperazine, and ethylenediamine.

6. The CMP polishing composition of claim 1, wherein the pH adjuster is selected from the group consisting of L-glutamic acid, L-histidine, alanine, serine, sulfuric acid, nitric acid, and ammonium hydroxide.

7. The CMP polishing composition of claim 1, wherein the chemical additive contains two or more phosphonic acid.

8. The CMP polishing composition of claim 1, wherein the chemical additive is selected from the group consisting of etidronic acid (1-hydroxyethane-1 1-diphosphonic acid), methylenediphosphonic acid, nitrilotris(methylene triphosphonic acid), phenylphosphonic acid, octylphosphonic acid, butylphosphonic acid, (aminomethyl)phosphonic acid, diisooctylphosphinic acid, iminodi(methylphosphonic acid), and 3-phosphonopropionic acid.

9. The CMP polishing composition of claim 1, wherein the chemical additive is etidronic acid (1-hydroxyethane-1 1-diphosphonic acid).

10. The CMP polishing composition of claim 1, wherein the composition further comprises from 0.0001 wt. % to 0.05 wt. %; preferably from 0.0005 wt. % to 0.025 wt. %, and more preferably from 0.001 wt. % to 0.01 wt. % of the biocide having active ingredients of 5-chloro-2-methyl-4-isothiazolin-3-one and 2-methyl-1-isothiazolin-3-one.

11. (canceled)

12. The CMP polishing composition of claim 1, the CMP composition comprises silica particles having silanol density <0.5 SiOH/nm², or SSA <150 m²/gm, etidronic acid, and L-glutamic acid.

13. The CMP polishing composition of claim 1, the CMP composition comprises silica particles having silanol density <0.5 SiOH/nm², or SSA <150 m²/gm, etidronic acid, and L-glutamic acid; wherein the silica particles are non-spherical and are not surface modified; the pH of the CMP polishing composition is from 2 to 4.

14. The CMP polishing composition of claim 1, the CMP composition comprises silica particles having silanol density <0.05 SiOH/nm² or SSA <150 m²/gm, etidronic acid, and L-glutamic acid; wherein the silica particles are non-spherical and are not surface modified; the pH of the CMP polishing composition is from 2 to 4.

15. The CMP polishing composition of claim 1, the CMP composition comprises silica particles having silanol density <0.01 SiOH/nm² or SSA <150 m²/gm, etidronic acid, and L-glutamic acid; wherein the silica particles are non-spherical and are not surface modified; the pH of the CMP polishing composition is from 2 to 4.

16. A method of CMP polishing a semiconductor substrate having at least one surface comprising silicon oxide film, comprising
providing the semiconductor substrate;
providing a polishing pad;
providing the CMP polishing composition in any of claim 1;
contacting the surface of the semiconductor substrate with the polishing pad and the CMP polishing composition; and
polishing the least one surface comprising silicon dioxide.

17. The method of claim 16; wherein the silicon oxide film is selected from the group consisting of Chemical vapor deposition (CVD), Plasma Enhance CVD (PECVD), High Density Deposition CVD (HDP), or spin on silicon oxide film.

18. The method of claim 16; wherein the semiconductor substrate further comprises a surface containing silicon nitride, and removal selectivity of SiO₂: SiN is 0.8 to 1.5, or 0.95 to 1.05.

19. (canceled)

20. A system of CMP polishing a semiconductor substrate having at least one surface comprising silicon oxide film, comprising
a. the semiconductor substrate;
b. the CMP polishing composition in claim 1;
c. a polishing pad;
wherein the at least one surface comprising silicon oxide film is in contact with the polishing pad and the CMP polishing composition.

21. The system of claim 20; wherein the silicon oxide film is selected from the group consisting of Chemical vapor deposition (CVD), Plasma Enhance CVD (PECVD), High Density Deposition CVD (HDP), or spin on silicon oxide film.

22. The system of claim 20; wherein the semiconductor substrate further comprises a surface containing silicon nitride, and removal selectivity of SiO₂: SiN is 0.8 to 1.5, or 0.95 to 1.05.

23. (canceled)

24. The method of claim 16; wherein in the CMP polishing composition:
the silica particles are non-spherical, or non-surface modified;
the pH adjuster is selected from the group consisting of amino acid selected from the group consisting of L-glutamic acid, L-histidine, alanine, glycine, cysteine, cystine, aspartic acid, valine, and serine; inorganic acid selected from the group consisting of nitric acid, sulfuric acid, hydrochloric acid and phosphoric acid; inorganic bases selected from the group consisting of ammonium hydroxide, sodium hydroxide, potassium hydroxide, cesium hydroxide, and tetramethylammonium hydroxide; and
the chemical additive is selected from the group consisting of etidronic acid (1-hydroxyethane-1 1-diphosphonic acid), methylenediphosphonic acid, nitrilotris(methylene triphosphonic acid), phenylphosphonic acid, octylphosphonic acid, butylphosphonic acid, (aminomethyl)phosphonic acid, diisooctylphosphinic acid, iminodi(methylphosphonic acid), and 3-phosphonopropionic acid.

25. The system of claim 20; wherein in the CMP polishing composition:
the silica particles are non-spherical, or non-surface modified;
the pH adjuster is selected from the group consisting of amino acid selected from the group consisting of L-glutamic acid, L-histidine, alanine, glycine, cysteine, cystine, aspartic acid, valine, and serine; inorganic acid selected from the group consisting of nitric acid, sulfuric acid, hydrochloric acid and phosphoric acid; inorganic bases selected from the group consisting of ammonium hydroxide, sodium hydroxide, potassium hydroxide, cesium hydroxide, and tetramethylammonium hydroxide; and
the chemical additive is selected from the group consisting of etidronic acid (1-hydroxyethane-1 1-diphosphonic acid), methylenediphosphonic acid, nitrilotris(methylene triphosphonic acid), phenylphosphonic acid, octylphosphonic acid, butylphosphonic acid, (aminomethyl)phosphonic acid, diisooctylphosphinic acid, iminodi(methylphosphonic acid), and 3-phosphonopropionic acid.
